(19) United States
(12) Patent Application Publication
(10) Pub. No.: US 2026/0309775 A1
(43) Pub. Date: Oct. 8, 2026

(54) CONDUCTIVE PROBING INTERFACE DEVICE

(71) Applicant: INTERNATIONAL BUSINESS MACHINES CORPORATION, ARMONK, NY (US)

(72) Inventors: Mark Christopher Johnson, ESSEX JUNCTION, VT (US); Theodore M. Levin, ALBANY, NY (US); David Michael Audette, Colchester, VT (US); Grant Wagner, Jericho, VT (US)

(21) Appl. No.: 19/173,779

(22) Filed: Apr. 8, 2025

(51) Int. Cl. G01R 31/28; G01R 1/073

(52) U.S. Cl. CPC G01R 31/2889; G01R 1/07342; G01R 1/07357; G01R 1/07378

(57) ABSTRACT

A probing tool apparatus to protect substrate pads on a substrate includes a frame. Conductive input points are on the frame. An elastic element is coupled to the frame. Contact probe pads are coupled to the elastic element and connected to the one or more conductive input points. The contact probe pads are positioned to be aligned with one or more of the substrate pads of a substrate.

### BACKGROUND

### Technical Field

The present disclosure generally relates to testing devices, and more particularly, to conductive probing interface device.

### Description of the Related Art

With modern bonding techniques it is often salient to have pristine surfaces to achieve successful bonding of interconnects in semiconductors, whether it be wafer to wafer, chip to wafer, chip to chip, etc. There may be a desire to test each wafer or chip before bonding and testing generally requires some kind of test probing. Current probe tips may be sharp relative to the small and flat surface of pads. For example, some probes have pointy tips that are designed to penetrate an underlying surface. Other probes may have a tip that is angled relative to the top surface of the test pad. And so, current probes with their pointy or angled ends have edges that often damage the contact surface of a pad being tested.

One approach uses a temporary bonded layer solution which is good and advisable for ultra-fine pitch interconnects, but there is need in the industry to protect interconnects prior to bonding at high pitches, such as 150um pitches that are becoming standard today. For these cases, where pitch is not so small, the probes to test at the pitch already exist, however, the probes may damage the surfaces of pads on the wafer.

### SUMMARY

According to an embodiment of the present disclosure, a probing tool apparatus includes a frame. Conductive input points are on the frame. An elastic element is coupled to the frame. Contact probe pads are coupled to the elastic element and connected to the one or more conductive input points. The contact probe pads are arranged to be aligned with a plurality of substrate pads of a semiconductor substrate.

According to another embodiment of the present disclosure, a probing tool apparatus includes a probe card. A plurality of probe pins are coupled to the probe card. The plurality of probe pins are arranged to be aligned with a plurality of substrate pads of a semiconductor substrate. A conductive interface device is configured for placement between the plurality of probe pins and the plurality of substrate pads. A plurality of conductive contact probe pads are in the conductive interface device. A substrate facing side of the plurality of conductive contact probe pads is positioned to contact the plurality of substrate pads and a probe card side of the plurality of conductive contact probe pads is positioned to interface with the plurality of probe pins.

According to another embodiment of the present disclosure, a method of protecting pads on a substrate during a probing session, includes removing a layer of oxide from a top surface of the pads on the substrate. A conductive interface device, including one or more conductive contact probe pads, is positioned in alignment with the pads on the substrate. A probe card including one or more probe pins is coupled to the conductive interface device. The conductive interface is positioned in between the probe card and the pads on the substrate. The probe card is moved into a probing position with the pads on the substrate. The conductive contact probe pads contact the probe pins from a first side of the conductive contact probe pads. The pads on the substrate with the layer of oxide removed contact the conductive contact probe pads, from a second side of the one or more conductive contact probe pads.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a front, exploded diagrammatic view of a probing system, according to an embodiment

FIG. 2 is a front, exploded diagrammatic view of a probing tool apparatus, consistent with embodiments of the present disclosure.

FIG. 3 is a front, exploded diagrammatic view of a probing tool apparatus, consistent with embodiments of the present disclosure.

FIG. 4 is a front, exploded diagrammatic view of a probing tool apparatus, consistent with embodiments of the present disclosure.

FIG. 5 is a front, exploded diagrammatic view of a probing tool apparatus, consistent with embodiments of the present disclosure.

FIG. 6 is a front, exploded diagrammatic view of a probing tool apparatus, consistent with embodiments of the present disclosure.

FIG. 7 is a front, exploded diagrammatic view of a probing tool apparatus, consistent with embodiments of the present disclosure.

### DETAILED DESCRIPTION

### Overview

In general, a probing tool apparatus is disclosed that provides a conductive interface device that protects pads on a substrate from damage when being probed. In some embodiments, the apparatus may consist only of the conductive interface device. The conductive interface device includes conductive probe pads that serve as a buffer conducting a probing signal from a probe signal source to pads of a substrate being tested. The probe pads interface with substrate pads while simultaneously conducting the probe signal. The conductive probe pads may be configured to protect the top surface of substrate pads from direct contact with probe pins when contact is made. Some embodiments further reduce (e.g., minimize) protection by providing an elastic element in the conductive interface device that lessens the pressure exerted on the top surface of substrate pads. Some embodiments will integrate one or more elements of a probe card directly into the conductive interface device so that probe pins may be connected directly to the conductive interface device. Some embodiments may be a system that integrates a probe card with the conductive interface.

According to an embodiment of the present disclosure, a probing tool apparatus includes a frame. Conductive input points are on the frame. An elastic element is coupled to the frame. Contact probe pads are coupled to the elastic element and connected to the one or more conductive input points. The contact probe pads are arranged to be aligned with a plurality of substrate pads of a semiconductor substrate.

According to an embodiment, which may be in combination with any of the previous embodiments, the contact probe pads include a distal end comprising a flat or planar contact surface disposed to contact a top surface of a substrate pad. As will be appreciated, the flat or planar surface reduces (e.g., minimizes) the potential penetration of the top surface of a substrate pad being probed.

According to an embodiment, which may be in combination with any of the previous embodiments, the contact probe pads include a distal end comprising rounded corners. Rounded corners protect the top surface of a substrate pad from damage which sometimes occurs when a probe is rectangular and has sharp edges.

According to an embodiment, which may be in combination with any of the previous embodiments, the elastic element is a layer of elastomer on the frame. An elastomer layer distributes the need for flexing across a wider area when contact with a substrate pad is made.

According to an embodiment, which may be in combination with any of the previous embodiments, individual sections of the elastomer layer are configured to flex in response to an individual probe of the one or more contact probe pads coming into contact with a top surface of an underlying substrate pad. By having individual sections of elastomer flex, the apparatus can accommodate uneven backpressure that can result from substrate pads having uneven heights.

According to an embodiment, which may be in combination with any of the previous embodiments, flexible wires are coupled between the one or more conductive input points and the one or more contact probe pads. Flexible wires provide a margin of freedom or variation in movement when a contact probe pad meets a substrate pad.

According to an embodiment, which may be in combination with any of the previous embodiments, flexible wires or springs coupled between an upper portion of the frame and a lower portion of the frame. Flexible wires or springs in the frame provide a margin of freedom or variation in movement of the frame when a contact probe pad meets a substrate pad.

According to an embodiment, which may be in combination with any of the previous embodiments, a cobra probe coupled to the one or more contact probe pads. Cobra probes are one type of tool that can be used to probe micron scale devices. Being adaptable to use with cobra probes provides the device compatibility with the scale of device fabrication the apparatus is configured to address. The probe contact pads protect the substrate pads from the sharp point of cobra probes which will damage substrate pad top surfaces beyond the tolerance allowed for micron scale pitch applications.

According to an embodiment, which may be in combination with any of the previous embodiments, the contact probe pads include a top contact pad and a bottom contact pad, and the elastic element is disposed between the top contact pad and a bottom contact pad. The two-pad arrangement provides improved conductivity since a pad has more area to contact and conduct a signal. By connecting the two pads with a flexible element in between, the strength of signal can be retained while relieving any damaging pressure to the top surface of the substrate pad.

According to an embodiment, which may be in combination with any of the previous embodiments, low-force probes are coupled to the one or more conductive input points. The one contact probe pads are arranged in between the low-force probes and the plurality of substrate pads. Being adaptable to use with low-force probes provides the device compatibility with the scale of device fabrication the apparatus is configured to address.

According to an embodiment, which may be in combination with any of the previous embodiments, micropillar probes are coupled to the one or more conductive input points. The contact probe pads are arranged in between the micropillar probes and the one or more substrate pads. Micro-pillar probes are one type of tool that can be used to probe micron scale devices. Being adaptable to use with micro-pillar probes provides the device compatibility with the scale of device fabrication the apparatus is configured to address. The probe contact pads protect the substrate pads from the sharp point of micropillar probes which will damage substrate pad top surfaces beyond the tolerance allowed for micron scale pitch applications.

According to another embodiment of the present disclosure, a probing tool apparatus includes a probe card. A plurality of probe pins are coupled to the probe card. The plurality of probe pins are arranged to be aligned with a plurality of substrate pads of a semiconductor substrate. A conductive interface device is configured for placement between the plurality of probe pins and the plurality of the substrate pads. A plurality of conductive contact probe pads are in the conductive interface device. A substrate facing side of the plurality of conductive contact probe pads is positioned to contact the plurality of the substrate pads and a probe card side of the plurality of conductive contact probe pads is positioned to interface with the plurality of probe pins.

According to an embodiment, which may be in combination with any of the previous embodiments, the apparatus includes an elastic element in the conductive interface, configured to flex unevenly as different ones of the plurality of conductive contact probe pads contact different ones of the plurality of the substrate pads at different times when the different ones of the plurality of the substrate pads have different height profiles above a top surface of the substrate. By providing an uneven flex at different places of the elastic element, the apparatus can accommodate different heights of substrate pads and relieve any potential damaging force on any one particular substrate pad.

According to an embodiment, which may be in combination with any of the previous embodiments, the apparatus includes rounded corners on the plurality of conductive contact probe pads. Rounded corners protect the top surface of a substrate pad from damage which sometimes occurs when a probe is rectangular and has sharp edges.

According to an embodiment, which may be in combination with any of the previous embodiments, the apparatus includes flexible wires in the conductive interface device coupled to the plurality of conductive contact probe pads, wherein the flexible wires flex unevenly as different ones of the plurality of conductive contact probe pads contact different ones of the plurality of the substrate pads at different times when the different ones of the plurality of the substrate pads have different height profiles above a top surface of the substrate. By providing an uneven flex at different places with flexible wires, the apparatus can accommodate different heights of substrate pads and relieve any potential damaging force on any one particular substrate pad.

According to an embodiment, which may be in combination with any of the previous embodiments, the apparatus includes low-force probes in the conductive interface device. The plurality of conductive contact probe pads are arranged in between the low-force probes and the plurality of the substrate pads. Low-force probes are one type of tool that can be used to probe micron scale devices. Being adaptable to use with low-force probes provides the device compatibility with the scale of device fabrication the apparatus is configured to address.

According to an embodiment, which may be in combination with any of the previous embodiments, the apparatus includes micropillar probes in the conductive interface device, and wherein the plurality of conductive contact probe pads are arranged in between the micropillar probes and the plurality of the substrate pads. Micro-pillar probes are one type of tool that can be used to probe micron scale devices. Being adaptable to use with micro-pillar probes provides the device compatibility with the scale of device fabrication the apparatus is configured to address. The probe contact pads protect the substrate pads from the sharp point of micropillar probes which will damage substrate pad top surfaces beyond the tolerance allowed for micron scale pitch applications.

According to another embodiment of the present disclosure, a method of protecting substrate pads on a substrate during a probing session, includes removing a layer of oxide from a top surface of the substrate pads. A conductive interface device, including one or more conductive contact probe pads, is positioned in alignment with the substrate pads. A probe card including one or more probe pins is coupled to the conductive interface device. The conductive interface device is positioned in between the probe card and the substrate pads, The probe card is moved into a probing position with the substrate pads. The conductive contact probe pads contact the probe pins from a first side of the conductive contact probe pads. The substrate pads with the layer of oxide removed contact the conductive contact probe pads, from a second side of the one or more conductive contact probe pads. As may be appreciated, by positioning a conductive interface device in between the probe card and the substrate pads, damage to the substrate pads is generally mitigated by the conductive interface device which still provides a conductive path for probe signals.

According to an embodiment, which may be in combination with any of the previous embodiments, the method includes flexing a layer of a frame in the conductive interface device as the substrate pads are contacted by the one or more conductive contact probe pads. Flexing a layer of the frame will distribute pressure on the substrate pads more evenly when the substrate pads have different heights which may make contact with the overlying conductive contact probe pad at different times as the conductive interface device is moved into probing position.

According to an embodiment, which may be in combination with any of the previous embodiments, the method includes unevenly flexing an element in the conductive interface device as the substrate pads are contacted by the one or more conductive contact probe pads. Unevenly flexing an element in the conductive interface device may further protect substrate pads from damage that may be caused by uneven pressure on individual substrate pads when the substrate pads have different heights.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the terms “below” or “stacked” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together—intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Device Under Test: a semiconductor substrate that includes one or more metal pads that are being probed for electrical performance.

Interface: a system through which one device is connected to another device.

Low-force Probe: IBM’s proprietary probe interface for µBumps.

Probe Card: a printed circuit board (PCB) that is the interface between the integrated circuit on a semiconductor substrate and a test head. The probe card provides an electrical path between the test system and the circuits on the wafer, thereby permitting the testing and validation of the circuits at the wafer level, usually before they are diced and packaged.

### Example Probing Device Configuration

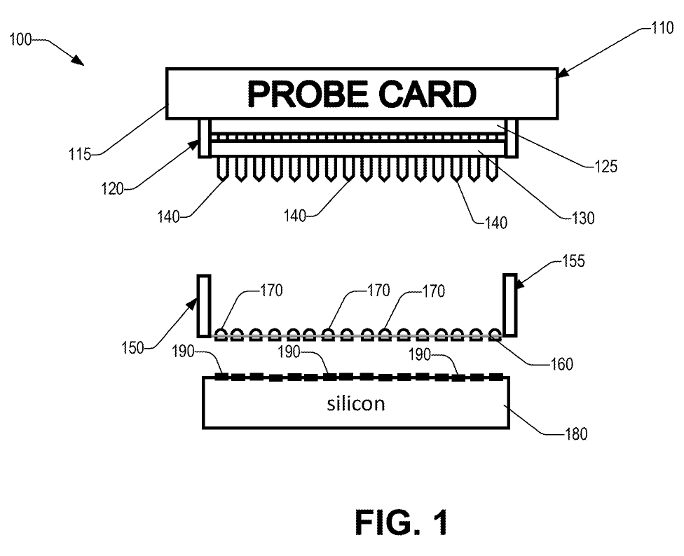

Referring now to FIG. 1, a probing system 100 is shown according to an embodiment. The system 100 generally includes a probe card 110 (sometimes referred to as a test probe head), a conductive interface device 150, and a substrate 180. The substrate 180 may be a semiconductor substrate (for example, silicon) with a plurality of metallic substrate pads 190, via which various devices, active or passive, formed in the substrate 180 may be tested through testing probes. Sometimes, the substrate 180 as a whole may be known as a device under test (DUT). The substrate pads 190 may be known as testing pads that can be spaced at approximately 150 micron pitch. Prior to probing, layers of oxide may be cleaned or removed from the top surface of the substrate pads 190 so that an efficient electrical contact is made with the conductive interface device 150. In an addition, any debris present on the substrate pads 190 may be removed. The probe card 110 may include a plurality of probe pins 140 attached to a probe card 115. A frame 120 of the probe card 110 may include an upper guide 125 and a lower guide 130 which cooperate to align the probe pins 140 into positions that align with substrate pads 190 on the underlying substrate of the substrate 180. The conductive interface device 150 includes a frame 155 configured for attachment and reattachment as an intermediary element to the frame 120 of the probe card 110. The conductive interface device 150 includes a support platform 160 as part of the frame 155. The support platform 160 may carry a plurality of conductive contact probe pads 170 that are positioned between and aligned with the overlying probe pins 140 and the underlying substrate pads 190.

As will be appreciated, the conductive interface device 150 provides protection to the substrate pads 190 by placing a conductive buffer element (the conductive contact probe pads 170) between the potentially destructive probe pins 140 and the substrate pads 190. As will be seen below in the description of various embodiments, the conductive interface device 150 includes various elements that adapt the conventional probe interface between probe pins 140 and substrate pads 190 to protect the substrate pads 190 from damage caused by contact of the probe pins 140 to the top surface of the substrate pads 190. Embodiments may include one or more elastic elements that can flex unevenly as the conductive contact probe pads 170 are pushed into contact with the substrate pads 190. As can be seen, the heights of respective substrate pads 190 may be slightly uneven. The elastic elements allow the different conductive contact probe pads 170 to make contact with their respective underlying substrate pad 190 at different times to accommodate the differences in height profiles. In one embodiment, the elastic element may be a layer of elastomer. Individual sections of the elastomer layer are configured to flex in response to an individual probe of the conductive contact probe pads 170 coming into contact with a top surface of an underlying substrate pad 190. Other embodiments may include flexible wires that flex unevenly so that conductive contact probe pads 170 (or other embodiments thereof) yield to an opposing backpressure created on contact with a substrate pad 190.

### Example Embodiments

In the example embodiments below, different embodiments of a conductive interface are shown relative to an underlying substrate 180 and substrate pads 190. The probe card 110 is omitted for sake of illustration, however, it will be understood that the probe pins 140 are to engage one or more conductive input points on the different conductive interfaces to complete the probe circuit. Some of the embodiments below show probe elements (for example, cobra probes, low-force probes, and micro-pillars) that may not necessarily be part of the conductive interface embodiments. In some embodiments, the probe elements may be part of a separate probe card device and are shown in the figures as elements passing through the upper guide of the interface frame aligned for contact with the different contact probe pads of the various embodiments. The upper guide part of the frames may have conductive through vias that provide an electrical connection with the probe elements and the conductive contact pads elements. In such embodiments, it should remain appreciated that the different contact probe pads have structural geometries configured to mitigate the different damaging aspects of the different probe elements. However, other embodiments may integrate the different contact probe elements so that the conductive interface remains compatible with existing probe cards that are configured to operate with any one or more of the different probe elements.

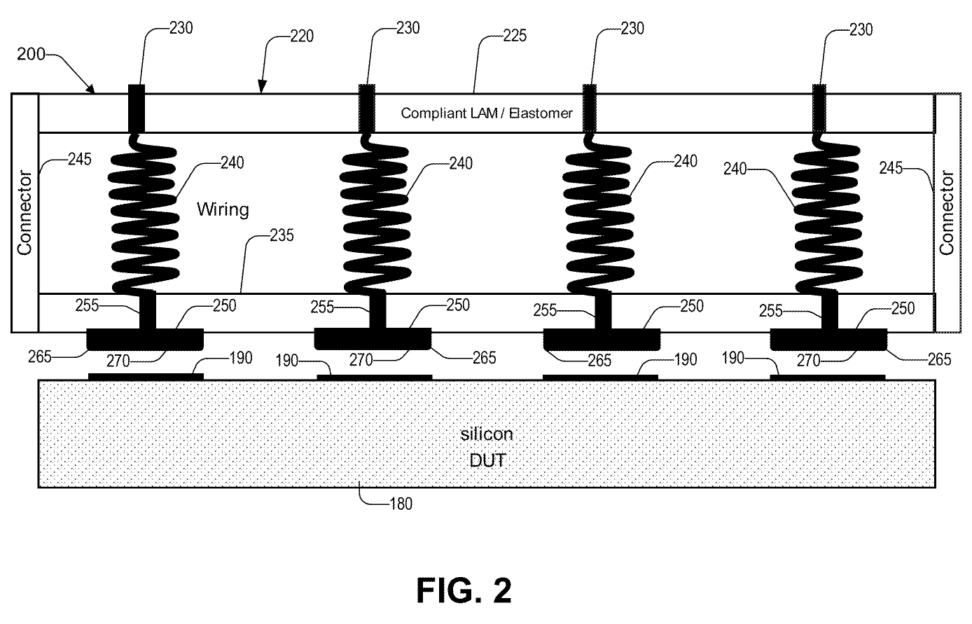

FIG. 2 shows a conductive interface device 200 according to an embodiment. The conductive interface device 200 includes one or more conductive contact probe pads 250 that are aligned for contact with the substrate pads 190 on the top surface of substrate 180. The conductive contact probe pads 250 provide an intermediary role taking probing signals from the probe card 110 (FIG. 1) that are passed through a connection from the probe pins 140 to the conductive interface device 200. The conductive interface device 200 includes a frame 220. The frame 220 may include an upper guide 225, a lower guide 235, and side connectors 245. The upper guide 225 may have one elastic element. For example, the upper guide 225 may be a compliant laminate or a layer of elastomer that flexes when pressure from the probe card 110 (FIG. 1) is applied. Conductive input points 230 may be present in the upper guide 225. The conductive input points 230 serve as the interface point for probe pins 140 (FIG. 1). A flexible wiring 240 may be connected to the internal end of the conductive input points 230. The flexible wiring 240 may be another elastic element that yields with pressure applied by the probe card 110. Conductive stems 255 may be present in the lower guide 235 that coupled the distal ends of the flexible wiring 240 to the conductive contact probe pads 250 on the bottom or substrate facing side of the lower guide 235. As can be seen, the bottom edges of conductive contact probe pads 250 may include rounded corners 265. The bottom or substrate facing side of the conductive contact probe pads 250 may be flat or planar contact surface 270 so that contact with the underlying substrate pad 190 is a substantially flat surface to flat surface interface. As may be appreciated, the rounded corners 265 and flat or planar contact surface 270 prevent any digging or scratching of the top surface of the substrate pads 190.

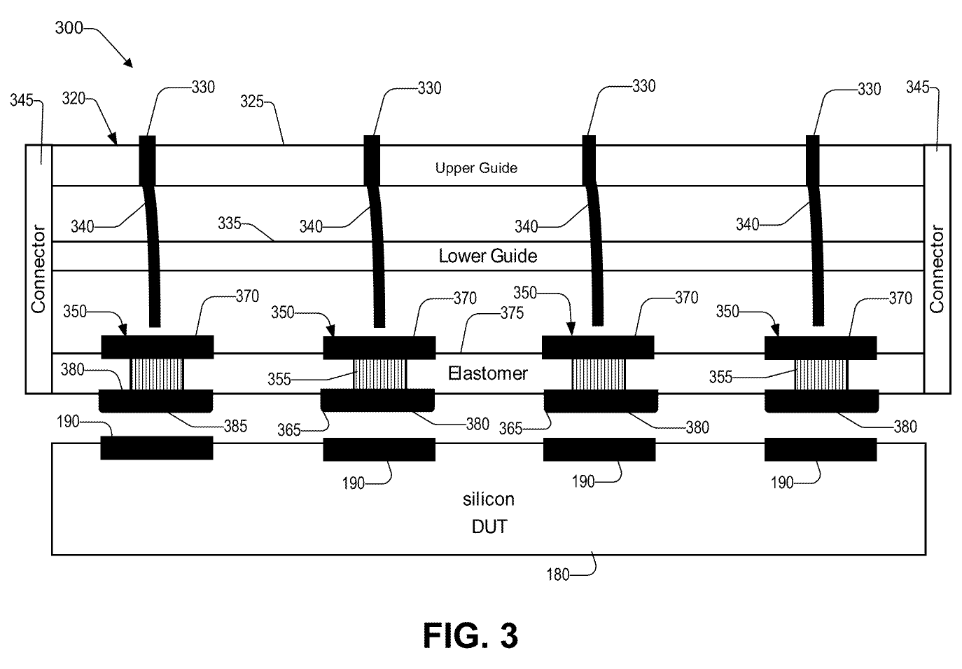

FIG. 3 shows a conductive interface device 300 according to an embodiment. The conductive interface device 300 is adapted for use with cobra probes 340. The conductive interface device 300 includes one or more conductive contact probes 350 that are aligned for contact with the substrate pads 190 on the top surface of substrate 180. A frame 320 includes an upper guide 325, a lower guide 335, and a layer of elastomer 375 as the bottom most level of the frame between side connectors 345. Conductive input points 330 may be present in the upper guide 325. The cobra probes 340 may be connected to the distal ends of the conductive input points 330. The conductive contact probes 350 may comprise a top contact pad 370 set into the layer of elastomer 375 and spaced from a distal end of the cobra probes 340. The top contact pad 370 may be connected to a bottom contact pad 380 through a conductive via or solid stem 355 that passes through the layer of elastomer 375. The bottom contact pad 380 may be similar to the conductive contact probes 350 in that the bottom contact pad 380 may have a flat bottom surface 385 and rounded corners 365. In operation, as the conductive interface device 300 is pressed into contact with the substrate 180, the bottom contact pads 380 engage their respective underlying substrate pads 190. The back pressure that results from contact may raise individual bottom contact pads 380 upward. The flexibility of the layer of elastomer 375 allows the individual conductive contact probes 350 to move upward within different sections of the layer of elastomer 375. As the top contact pads 370 move upward with their respective bottom contact pads 380, the gap between the overlying cobra probe 340 and top contact pad 370 closes until a conductive connection is made completing the probe circuit through the conductive input points 330.

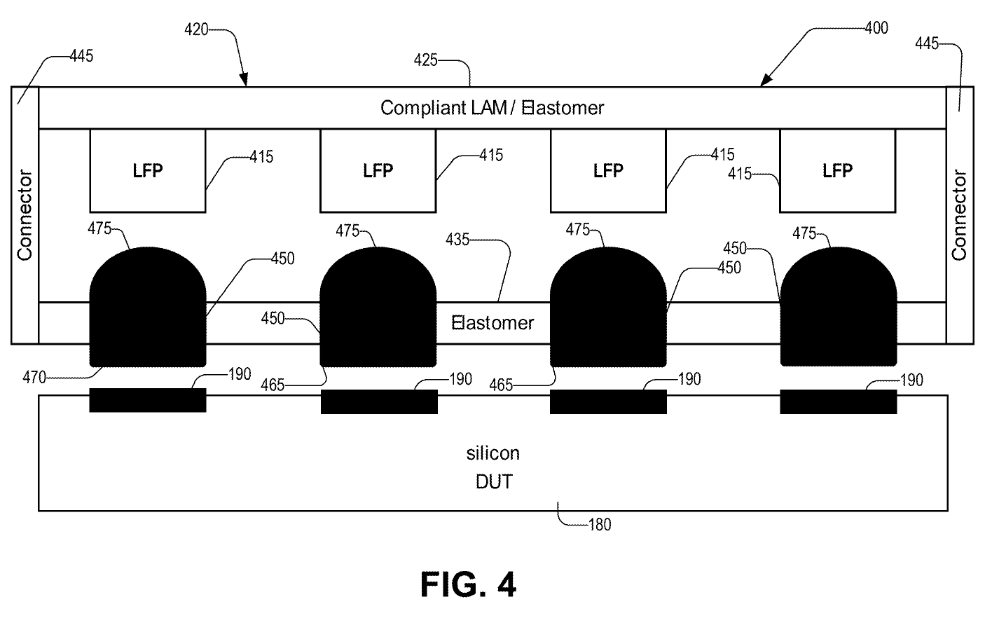

FIG. 4 shows a conductive interface device 400 according to an embodiment. The conductive interface device 400 is adapted for use with low-force probes 415. The conductive interface device 400 includes one or more conductive contact probes 450 that are aligned for contact with the substrate pads 190 on the top surface of substrate 180. A frame 420 includes an upper guide 425, a lower guide 435, and side connectors 445. The upper guide 425 and/or the lower guide 435 may be an elastic element such as a layer of elastomer. In some embodiments, the upper guide 425 comprises a compliant laminate. The low-force probes 415 may be connected to a bottom side of the upper guide 425. The upper guide 425 may be a compliant laminate that has conductive through vias for electrical connection with the low-force probes 415. The conductive contact probes 450 may be positioned in the lower guide 435 in alignment between the overlying low-force probes 415 and the underlying substrate pads 190. In a pre-test position, a gap is present between the bottom of the low-force probes 415 and the top side of the conductive contact probes 450. The conductive contact probes 450 may include rounded corners 465 and/or a flat bottom surface 470. The top side of the conductive contact probes 450 may be round or spherical. The height profile of the conductive contact probes 450 may extend above the top surface of the lower guide 435 and below the bottom surface of the lower guide 435. In operation, as a probe card 110 (FIG. 1) is pressed down onto the conductive interface device 400, once the bottom surface 470 of conductive contact probes 450 engage the substrate pads 190, the back pressure pushes the conductive contact probes 450 upward. The elastic lower guide 435 allows the conductive contact probes 450 to move upward into contact with the overlying low-force probes 415. The round top surfaces 475 provide a cushioning buffer against the bottom of the low-force probes 415.

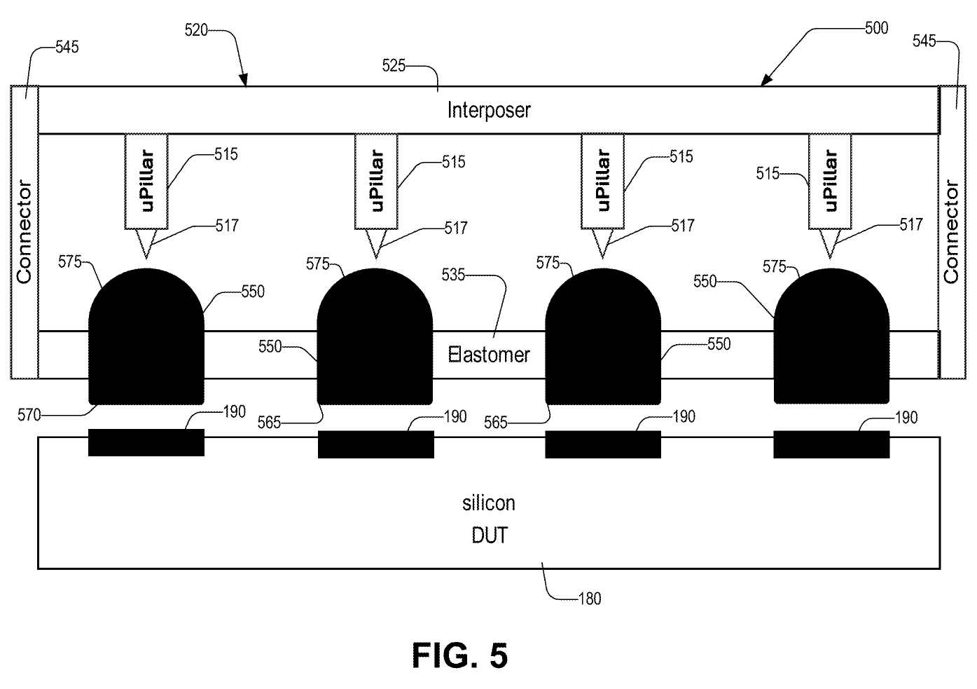

FIG. 5 shows a conductive interface device 500 according to an embodiment. The conductive interface device 500 is adapted for use with micro-pillar probes 515 (sometimes referred to as “micron probes”). The conductive interface device 500 is similar in every respect to the conductive interface device 400, using like numbers in the 500 series for the same elements in the 400 series of FIG. 4 (for example, frame 520, upper guide 525, and contact probe rounded corners 565), except for the micro-pillar probes 515 which have points 517. As can be appreciated, the points 517 would normally damage substrate pads 190 beyond any acceptable specification for pad devices that are manufactured in the 150 micron pitch scale. However, the height profile of conductive contact probes 550 and the rounded top surfaces 575 provide a buffer that receives any penetration by the points 517. The elastic lower guide 535 yields to back pressure exerted by the substrate pads 190 against the bottom surface 570 of conductive contact probes 550 ensuring protection from damage during probing of the substrate pads 190.

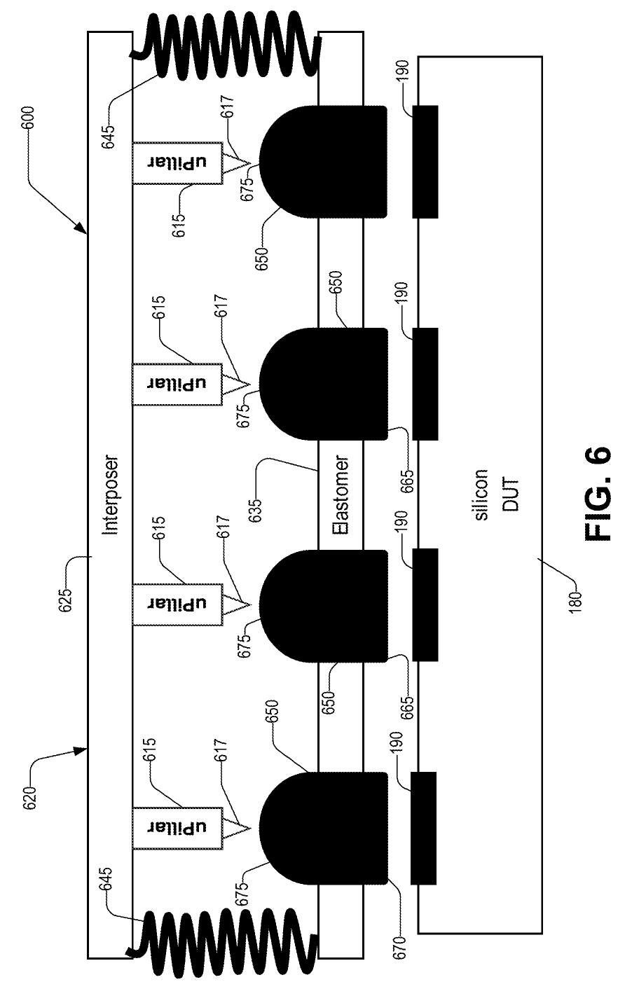

FIG. 6 shows a conductive interface device 600 according to an embodiment. The conductive interface device 600 is similar in every respect to the conductive interface device 500 shown in FIG. 5, using like numbers in the 600 series for the same elements in the 500 series of FIG. 5, (for example, micro-pillar probes 615, points 617, upper guide 625, elastic lower guide 635, probe rounded corners 665), and rounded top surfaces 675) except for flexible wires/springs 645 that replace the connectors 545. The wires/springs 645 provide additional flexibility in the frame 620 so that when back pressure exerted by the substrate pads 190 against the bottom surface 670 of conductive contact probes 650 occurs, the frame 620 yields to the backpressure ensuring that the substrate pads 190 are not damaged by probing contact.

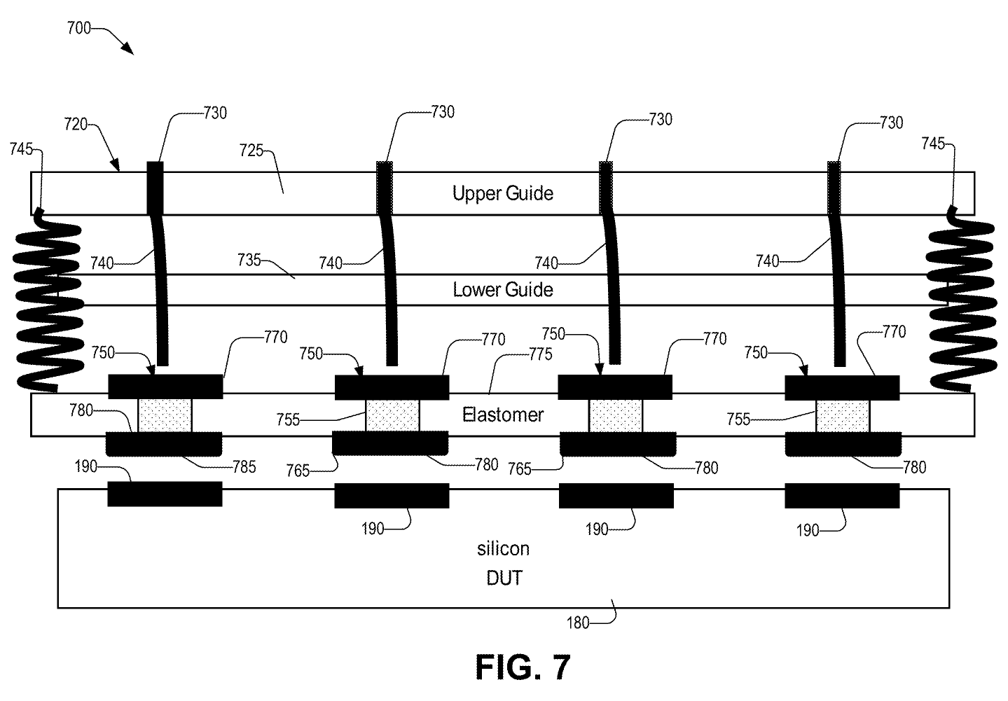

FIG. 7 shows a conductive interface device 700 according to an embodiment. The conductive interface device 700 is adapted for use with cobra probes 740 similar to the conductive interface device 300 of FIG. 3. The conductive interface device 700 includes one or more conductive contact probes 750 that are aligned for contact with the substrate pads 190 on the top surface of substrate 180. A frame 720 includes an upper guide 725, a lower guide 735, and a layer of elastomer 375 as the bottom most level of the frame 720. The side portions of frame 720 are flexible wires or springs 745 which connect the side edges of upper guide 725, lower guide 735, and elastomer layer 775 together. Conductive input points 730 may be present in the upper guide 725. The cobra probes 740 may be connected to the distal ends of the conductive input points 730. The conductive contact probes 750 may comprise a top contact pad 770 set into the layer of elastomer 775 and spaced from a distal end of the cobra probes 740. The top contact pad 770 may be connected to a bottom contact pad 780 through a conductive via or solid stem 755 that passes through the layer of elastomer 775. The bottom contact pad 780 may be similar to the conductive contact probes750 in that the bottom contact pad 780 may have a flat bottom surface 785 and rounded corners 765. In operation, as the conductive interface device 700 is pressed into contact with the substrate 180, the bottom contact pads 780 engage their respective underlying substrate pads 190. The back pressure that results from contact may raise individual bottom contact pads 780 upward. The flexibility of the layer of elastomer 775 allows the individual conductive contact probes 750 to move upward within different sections of the layer of elastomer 775. As the top contact pads 770 move upward with their respective bottom contact pads 780, the gap between the overlying cobra probe 740 and top contact pad 770 closes until a conductive connection is made completing the probe circuit through the conductive input points 730.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A probing tool apparatus, comprising:
a frame;
one or more conductive input points on the frame;
an elastic element coupled to the frame; and
one or more contact probe pads coupled to the elastic element and connected to the one or more conductive input points,
wherein the one or more contact probe pads are arranged to be aligned with a plurality of substrate pads of a semiconductor substrate.

2. The apparatus of claim 1, wherein the one or more contact probe pads include a distal end, the distal end comprising a flat or planar contact surface disposed to contact a top surface of an underlying substrate pad of the plurality of substrate pads.

3. The apparatus of claim 1, wherein the one or more contact probe pads include a distal end, the distal end comprising rounded corners.

4. The apparatus of claim 1, wherein the elastic element is a layer of elastomer attached to the frame.

5. The apparatus of claim 4, wherein individual sections of the elastomer layer are configured to flex in response to an individual contact probe pad of the one or more contact probe pads coming into contact with a top surface of an underlying substrate pad of the plurality of substrate pads.

6. The apparatus of claim 1, further comprising one or more flexible wires coupled between the one or more conductive input points and the one or more contact probe pads.

7. The apparatus of claim 1, further comprising one or more flexible wires or springs coupled between an upper portion of the frame and a lower portion of the frame.

8. The apparatus of claim 1, further comprising a cobra probe coupled to the one or more contact probe pads.

9. The apparatus of claim 1, wherein:
the one or more contact probe pads include a top contact pad and a bottom contact pad; and
the elastic element is disposed between the top contact pad and the bottom contact pad.

10. The apparatus of claim 1, further comprising low-force probes coupled to the one or more conductive input points, wherein the one or more contact probe pads are arranged in between the low-force probes and the plurality of substrate pads.

11. The apparatus of claim 1, further comprising micropillar probes coupled to the one or more conductive input points, wherein the one or more contact probe pads are arranged in between the micropillar probes and the plurality of substrate pads.

12. A probing tool apparatus, comprising:
a probe card;
a plurality of probe pins coupled to the probe card, wherein the plurality of probe pins are arranged to be able to be aligned with a plurality of substrate pads of a substrate;
a conductive interface device configured for placement between the plurality of probe pins and the plurality of the substrate pads; and
a plurality of conductive contact probe pads in the conductive interface device, wherein a substrate facing side of the plurality of conductive contact probe pads is positioned to contact the plurality of the substrate pads and a probe card side of the plurality of conductive contact probe pads is positioned to interface with the plurality of probe pins.

13. The apparatus of claim 12, further comprising an elastic element in the conductive interface device, configured to flex unevenly as different ones of the plurality of conductive contact probe pads contact different ones of the plurality of the substrate pads at different times when the different ones of the plurality of the substrate pads have different height profiles above a top surface of the substrate.

14. The apparatus of claim 12, further comprising rounded corners on the plurality of conductive contact probe pads.

15. The apparatus of claim 12, further comprising one or more flexible wires in the conductive interface device coupled to the plurality of conductive contact probe pads, wherein the flexible wires flex unevenly as different ones of the plurality of conductive contact probe pads contact different ones of the plurality of the substrate pads at different times when the different ones of the plurality of the substrate pads have different height profiles above a top surface of the substrate.

16. The apparatus of claim 12, further comprising low-force probes in the conductive interface, and wherein the plurality of conductive contact probe pads are arranged in between the low-force probes and the plurality of the substrate pads.

17. The apparatus of claim 12, further comprising micropillar probes in the conductive interface, and wherein the plurality of conductive contact probe pads are arranged in between the micropillar probes and the plurality of the substrate pads.

18. A method of protecting pads on a substrate during a probing session, comprising:
removing a layer of oxide from a top surface of the pads on the substrate;
positioning a conductive interface device, including one or more conductive contact probe pads, in alignment with the pads on the substrate;
coupling a probe card including one or more probe pins to the conductive interface device, wherein the conductive interface device is positioned in between the probe card and the pads on the substrate;
moving the probe card into a probing position with the pads on the substrate;
contacting the one or more conductive contact probe pads with the probe pins from a first side of the one or more conductive contact probe pads; and
contacting the pads on the substrate with the layer of oxide removed, with the one or more conductive contact probe pads, from a second side of the one or more conductive contact probe pads.

19. The method of claim 18, further comprising flexing a layer of a frame in the conductive interface device as the pads on the substrate are contacted by the one or more conductive contact probe pads.

20. The method of claim 18, further comprising unevenly flexing an element in the conductive interface device as the pads on the substrate are contacted by the one or more conductive contact probe pads.
